(19) United States
(12) Patent Application Publication
(10) Pub. No.: US 2013/0256741 A1
(43) Pub. Date: Oct. 3, 2013

(54) Siloxane Compositions Suitable For Forming Encapsulants

(71) Applicants: Brian R. Harkness, Midland, MI (US); Ann W. Norris, Blacksburg, VA (US); Shellene K. Thurston, Saginaw, MI (US)

(72) Inventors: Brian R. Harkness, Midland, MI (US); Ann W. Norris, Blacksburg, VA (US); Shellene K. Thurston, Saginaw, MI (US)

(21) Appl. No.: 13/991,828

(22) PCT Filed: Dec. 6, 2011
(86) PCT No.: PCT/US11/63474

§ 371 Date: Jun. 5, 2013

Related U.S. Application Data
(60) Provisional application No. 61/420,910, filed on Dec. 8, 2010.

(51) Int. Cl. H01L 33/56

(52) U.S. Cl. CPC H01L 33/56
USPC 257/100; 528/31; 524/779; 252/500

(57) ABSTRACT

A composition of the present invention includes an organopolysiloxane component (A) comprising at least one of a disiloxane, a trisiloxane, and a tetrasiloxane, and has at least one of an alkyl group and an aryl group and has an average of at least two alkenyl groups per molecule. Component (A) has a number average molecular weight less than or equal to 1500 (g/mole). The composition further includes an organohydrogensiloxane component (B) having at least one of an alkyl group and an aryl group and having an average of at least two silicon-bonded hydrogen atoms per molecule. Component (B) has a number average molecular weight less than or equal to 1500 (g/mole). The composition yet further includes a catalytic amount of a hydrosilylation catalyst component (C). A product of the present invention is the reaction product of the composition, which may be used to make a light emitting diode.

### CROSS-REFERENCE TO RELATED APPLICATIONS

This application claims the benefit of U.S. Provisional Patent Application Ser. No. 61/420,910, filed on Dec. 8, 2010, which is incorporated herein by reference in its entirety.

### FIELD OF THE INVENTION

The present invention generally relates to a siloxane composition suitable for forming encapsulants and, more specifically, to a composition comprising an organopolysiloxane component, an organohydrogensiloxane component, and a hydrosilylation catalyst component, and to a product formed therefrom.

### DESCRIPTION OF THE RELATED ART

Light emitting diodes (LEDs) are well known in the art, and generally comprise one or more diodes (that emit light when activated) that are encapsulated, i.e., encased, in an encapsulant. LED designs utilizing either flip chip or wire bonded chips are connected to the diode to provide power to the diode. When bonding wires are present, a portion of the bonding wires is at least partially encapsulated along with the diode. When LEDs are activated and emitting light, a rapid rise in temperature occurs, subjecting the encapsulant to thermal shock. Accordingly, when the LED is turned on and off repeatedly, the encapsulant is exposed to temperature cycles. In addition to normal use, LEDs are also exposed to environmental changes in temperature and humidity, as well as subject to physical shocks. Therefore, encapsulation is required for optimal performance.

Epoxy resins are generally used as encapsulants for LEDs. However, since many epoxy resins have a high modulus, i.e., a high elastic modulus, the portion of the bonding wires of the LED that are encapsulated proximal the diode are subjected to stress from expansion and contraction of the encapsulant, and may break as a result of temperature cycling. Further, cracks may develop within the encapsulant itself. Epoxy resins also tend to yellow over time, which reduces LED brightness and changes color of the light emitted from the LED. This yellowing problem is particularly problematic for white and blue colored LEDs. Yellowing of the epoxy resin is believed to result from decomposition of the encapsulant induced by the aforementioned temperature cycles of the LED and/or absorption of UV-light emitted by the LED.

Since siloxane compositions employing silicone resins and copolymers exhibit comparatively superior heat resistance, moisture resistance and retention of transparency relative to epoxy resins, in recent years, LEDs that use siloxane compositions to form encapsulants, primarily blue LEDs and white LEDs, have become more prevalent. Previously disclosed siloxane compositions generally have a relatively high viscosity, which makes dispense methodologies for encapsulating the LEDs difficult and therefore more expensive, as well as detrimentally affecting phosphor settling rates and increasing bubble entrapment. Many of the aforementioned encapsulants also have refractive indices and optical transparencies which make them undesirable for use in LEDs. Many of the aforementioned encapsulants are also too soft, i.e., the aforementioned encapsulants have low Shore A or Shore 00 hardness values, which make them undesirable for some LED applications.

Accordingly, there remains an opportunity to provide an improved composition. There also remains an opportunity to provide an improved product relative to the prior art.

### SUMMARY OF THE INVENTION

The present invention provides a composition. The composition comprises an organopolysiloxane component (A) comprising at least one of a disiloxane, a trisiloxane, a tetrasiloxane, a pentasiloxane, and a hexasiloxane. The organopolysiloxane component (A) has at least one of an alkyl group and an aryl group and has an average of at least two alkenyl groups per molecule. The organopolysiloxane component (A) has a number average molecular weight less than or equal to 1500. The composition further comprises an organohydrogensiloxane component (B) having at least one of an alkyl group and an aryl group. The organohydrogensiloxane component (B) has an average of at least two silicon-bonded hydrogen atoms per molecule, and has a number average molecular weight less than or equal to 1500. The composition yet further comprises a catalytic amount of a hydrosilylation catalyst component (C).

The composition can be cured to form a product, such as lenses or encapsulants for making various devices, such as, but not limited to, light emitting diodes.

### DETAILED DESCRIPTION OF THE INVENTION

A composition comprises an organopolysiloxane component (A), an organohydrogensiloxane component (B), and a hydrosilylation catalyst component (C). The composition may be reacted, i.e., cured, to form a product, which is described in further detail below. The product is especially suitable for use as an encapsulant. For example, the composition can be applied on a substrate, e.g. a diode, to form a light emitting diode (LED), which is described in further detail below. The product may also be used for other purposes, such as for lenses, photonic devices, etc.

The organopolysiloxane component (A), hereinafter component (A), generally comprises at least one of a disiloxane, a trisiloxane, a tetrasiloxane, a pentasiloxane, and a hexasiloxane. In other words, component (A) may include any one of the disiloxane, the trisiloxane, the tetrasiloxane, the pentasiloxane, or the hexasiloxane, or combinations of the disiloxane, the trisiloxane, the tetrasiloxane, the pentasiloxane, and/or the hexasiloxane, all of which is described in further detail below.

Component (A) has at least one of an alkyl group and an aryl group. In other words, component (A) has an alkyl group, or an aryl group, or a combination of alkyl and aryl groups. Suitable alkyl groups for purposes of the present invention include, but are not limited to, methyl, ethyl, propyl, 1-methylethyl, butyl, 1-methylpropyl, 2-methylpropyl, 1,1-dimethylethyl, pentyl, 1-methylbutyl, 1-ethylpropyl, 2-methylbutyl, 3-methylbutyl, 1,2-dimethylpropyl, 2,2-dimethylpropyl, hexyl, heptyl, octyl, nonyl, and decyl groups. Other suitable alkyl groups for purposes of the present invention include cycloalkyl groups, such as cyclopentyl, cyclohexyl, and methylcyclohexyl groups. In certain embodiments, component (A) includes at least one methyl group, alternatively at least two methyl groups, alternatively at least four methyl groups, alternatively at least six methyl groups. Suitable aryl groups for purposes of the present invention include, but are not limited to, phenyl and naphthyl groups; alkaryl groups, such as tolyl and xylyl groups; and aralkyl groups, such as benzyl and phenethyl groups. It is to be appreciated that component (A) may include any combination of two or more of the aforementioned aryl groups. In one embodiment, component (A) has at least one phenyl group. In certain embodiments, component (A) includes at least two phenyl groups; however, it is to be appreciated that in other embodiments, component (A) is free of any phenyl groups. Component (A) may include one or more aryl groups different than the phenyl groups, such as the aryl groups described and exemplified above. It is to be appreciated that component (A) may include any combination of the aforementioned alkyl groups and/or aryl groups. In addition, if component (A) includes two or more alkyl groups, the alkyl groups may be the same as or different than each other, likewise if component (A) includes two or more aryl groups.

Component (A) has an average of at least two alkenyl groups per molecule, alternatively at least three alkenyl groups per molecule. The alkenyl groups typically have from two to ten carbon atoms, more typically from two to six carbon atoms, most typically from two to four carbon atoms. In one embodiment, the alkenyl groups have two carbon atoms. Suitable alkenyl groups, for purposes of the present invention, include, but are not limited to, vinyl, allyl, butenyl, hexenyl, and octenyl groups. In certain embodiments, component (A) includes at least two vinyl groups per molecule, alternatively at least three vinyl groups per molecule. It is to be appreciated that component (A) may include any combination of the aforementioned alkenyl groups. In addition, component (A) can include alkenyl groups that are the same as or different than each other.

In certain embodiments, component (A) comprises the disiloxane having the formula:

R¹R²R³SiOSiR¹R²R³ (I)

wherein each R¹, R², and R³ independently comprises an alkyl group, an aryl group, or an alkenyl group. Suitable alkyl, aryl, and alkenyl groups are as described and exemplified above.

In certain embodiments, the disiloxane has the formula:

ViPhMeSiOSiViPhMe (i)

wherein Vi is a vinyl group, Ph is a phenyl group, and Me is a methyl group. In these embodiments, the disiloxane of formula (I) imparts the composition with excellent homogeneity and with low viscosity and imparts the product with high modulus and an increased refractive index due to the phenyl groups, which is described in further detail below. It is believed that the presence of phenyl groups in these types of compounds results in higher boiling points with lower volatility, while maintaining low viscosity of the composition. It is to be appreciated that component (A) may include a combination of two or more different organopolysiloxanes (A) having formulas (I) and/or (i).

In certain embodiments, the organopolysiloxane (A) comprises at least one of the trisiloxane and the tetrasiloxane, each of the trisiloxane and the tetrasiloxane independently having the formula:

(R¹R³₂SiO)₄₋ₐSiR⁴ₐ (II)

wherein each R¹, R³, and R⁴ independently comprises an alkyl group, an aryl group, or an alkenyl group, and subscript a is 0 for the tetrasiloxane or 1 for the trisiloxane. Suitable alkyl, aryl, and alkenyl groups are as described and exemplified above.

In certain embodiments, each of the trisiloxane and the tetrasiloxane independently have the formula:

(ViR³₂SiO)₄₋ₐSiR⁴ₐ (ii)

wherein Vi is a vinyl group, each R³ and R⁴ independently comprises a phenyl group or a methyl group, and subscript a is 0 for the tetrasiloxane or 1 for the trisiloxane. In these embodiments, the trisiloxane and/or the tetrasiloxane of formula (II) imparts the composition with excellent homogeneity and low viscosity and imparts the product with high modulus and a refractive index which can be tailored depending upon whether R⁴ is a methyl or phenyl group, as described in further detail below. It is to be appreciated that component (A) may include a combination of two or more different organopolysiloxanes (A) having formulas (II) and/or (ii). In addition, component (A) may include a combination of two or more different organopolysiloxanes (A) having formulas (I), (i), (II), and/or (ii).

In certain embodiments, the organopolysiloxane (A) comprises at least one of the pentasiloxane and the hexasiloxane, each of the pentasiloxane and the hexasiloxane independently having the formula:

(R¹R³₂SiO)₆₋ₐSiR⁴ₐ (III)

wherein each R¹, R³, and R⁴ independently comprises an alkyl group, an aryl group, or an alkenyl group, and subscript a is 0 for the hexasiloxane or 1 for the pentasiloxane. Suitable alkyl, aryl, and alkenyl groups are as described and exemplified above.

In certain embodiments, each of the pentasiloxane and the hexasiloxane independently have the formula:

(ViR³₂SiO)₆₋ₐSiR⁴ₐ (iii)

wherein Vi is a vinyl group, each R³ and R⁴ independently comprises a phenyl group or a methyl group, and subscript a is 0 for the hexasiloxane or 1 for the pentasiloxane. In these embodiments, the pentasiloxane and/or the hexasiloxane of formula (iii) imparts the composition with excellent homogeneity and low viscosity and imparts the product with high modulus and a refractive index which can be tailored depending upon whether R⁴ is a methyl or phenyl group, as described in further detail below. It is to be appreciated that component (A) may include a combination of two or more different organopolysiloxanes (A) having formulas (III) and/or (iii). In addition, component (A) may include a combination of two or more different organopolysiloxanes (A) having formulas (I), (i), (II), (ii), (III), and/or (iii).

Methods of preparing component (A) as described above and represented by formulas (I), (i), (II), (ii), (III), and (iii) are well known to those skilled in the silicone art. Component (A) as described and exemplified above, and other specific examples of suitable organopolysiloxanes (A) for purposes of the present invention, such as 1,3-dimethyl-1,3-diphenyl-1,3-divinyldisiloxane, 1,5-divinyl-3-(dimethylvinylsiloxy)-1,1,5,5-tetramethyl-3-phenyltrisiloxane, 1,5-divinyl-3-(dimethylvinylsiloxy)-1,1,5,5-tetramethyl-3-methyltrisiloxane, 1,1,3,3-tetramethyl-1,3-divinyldisiloxane, tetrakis (vinyldimethylsiloxy)silane, tetrakis(vinyldiphenylsiloxy)silane, and tetrakis(vinylmethylphenylsiloxy)silane, 1,1,5,5-tetramethyl-1,5-divinyl-3-diphenyltrisiloxane, 1,1,7,7-tetramethyl-1,7-divinyl-3,5-diphenyltetrasiloxane, 1,1,9,9-tetramethyl-1,9-divinyl-3,5,7-triphenylpentasiloxane, 1,1,11,11-tetramethyl-1,1′-divinyl-3,5,7,9-tetraphenylhexasiloxane, and additional penta and hexasiloxanes with methylphenyl and/or diphenyl siloxanes, are available from Gelest of Morrisville, Pa.

Component (A) has a number average molecular weight no greater than 1500, alternatively a number average molecular weight no greater than 1000, alternatively a number average molecular weight no greater than 800. Generally, decreasing the number average molecular weight of the organopolysiloxane (A) correlates to lower viscosity, which facilitates easier dispense.

In certain embodiments, such as when component (A) is of the formula (I) or (i) as described above, component (A) is typically present in an amount ranging from 30 to 65, more typically from 35 to 45, most typically from 38 to 44, parts by weight, based on 100 parts by weight of the composition. In other embodiments, such as when component (A) is of the formula (II) or (ii) as described above, component (A) is typically present in an amount ranging from 20 to 60, more typically from 25 to 45, most typically from 20 to 40, parts by weight, based on 100 parts by weight of the composition. It is to be appreciated that component (A), and therefore the composition, may include any combination of two or more of the aforementioned organopolysiloxanes (A).

The organohydrogensiloxane component (B), hereinafter component (B), has at least one of an alkyl group and an aryl group. In other words, component (B) has an alkyl group, or an aryl group, or a combination of alkyl and aryl groups. Suitable alkyl and aryl groups for component (B) are as described and exemplified above with description of component (A). In certain embodiments, component (B) has at least one phenyl group. In these embodiments, component (B) may include one or more aryl groups different than phenyl groups. Component (B) has an average of at least two silicon-bonded hydrogen atoms per molecule, alternatively at least three silicon-bonded hydrogen atoms per molecule.

In certain embodiments, component (B) comprises a silicone resin having the formula:

(R⁶R⁷₂SiO_{1/2})_{y}(R⁵SiO_{3/2})ₓ (IV)

wherein each R⁵ and R⁶ independently comprises an alkyl group, an aryl group, an alkenyl group, or a hydrogen atom, each R⁷ independently comprises an alkyl group, an aryl group, or an alkenyl group, subscript x ranges from 0.2 to 0.6, more typically from 0.35 to 0.45, most typically 0.4, and x+y=1. Suitable alkyl, aryl, and alkenyl groups for formula (IV) are as described and exemplified above with the organopolysiloxane (A).

In certain embodiments, the silicone resin has the formula:

(HR⁷₂SiO_{1/2})_{y}(R⁵SiO_{3/2})ₓ (iv)

wherein each R⁵ and R⁷ independently comprises a phenyl group or a methyl group, subscript x ranges from 0.2 to 0.6, more typically from 0.35 to 0.45, most typically 0.4, and x+y=1. In these embodiments, the organohydrogensiloxane (B) of formula (Iv) imparts the composition with excellent homogeneity and low viscosity, and imparts the product with high modulus and an increased refractive index, which is described in further detail below. It is to be appreciated that component (B) may include a combination of two or more different organohydrogensiloxanes (B) having formulas (IV) and/or (iv).

In certain embodiments, component (B) comprises a siloxane having the formula:

(R⁶R⁷₂SiO)(R⁵₂SiO)_{z}(SiR⁶R⁷₂) (V)

wherein each R⁵ and R⁶ independently comprises an alkyl group, an aryl group, an alkenyl group, or a hydrogen atom, each R⁷ independently comprises an alkyl group, an aryl group, or an alkenyl group, and subscript z≧1, more typically 5≧z≧1, most typically 2.5≧z≧1. Suitable alkyl, aryl, and alkenyl groups for formula (V) are as described and exemplified above with description of the organopolysiloxane (A).

In certain embodiments, the siloxane has the formula:

(HR⁷₂SiO)(R⁵₂SiO)_{z}(SiHR⁷₂) (v)

wherein each R⁵ and R⁷ independently comprises a phenyl group or a methyl group, and 5≧z≧1, more typically 2.5≧z≧1, most typically subscript z=2.5, alternatively subscript z=1. In these embodiments, the organohydrogensiloxane (B) of formula (v) imparts the composition with excellent homogeneity and low viscosity and imparts the product with high modulus and an increased refractive index, which is described in further detail below. It is to be appreciated that component (B) may include a combination of two or more different organohydrogensiloxanes (B) having formulas (V) and/or (v). In addition, component (B) may include a combination of two or more different organohydrogensiloxanes (B) having formulas (IV), (iv), (V), and/or (v).

Methods of preparing component (B) as described above and represented by formulas (IV), (iv), (V), and (v), are well known to those skilled in the silicone art. Component (B) as described and exemplified above and other specific examples of suitable organohydrogensiloxanes (B) for purposes of the present invention, such as 1,1,5,5-tetramethyl-3,3-diphenyltrisiloxane, 1,3-dimethyl-1,3-diphenyl-1,3-dihydrodisiloxane, 1,5-dihydro-3-(dimethylhydrosiloxy)-1,1,5,5-tetramethyl-3-phenyltrisiloxane, 1,5-dihydro-3-(dimethylhydrosiloxy)-1,1,5,5-tetramethyl-3-methyltrisiloxane, 1,1,3,3-tetramethyl-1,3-dihydrodisiloxane, tetrakis(hydrodimethylsiloxy)silane, tetrakis(hydrodiphenylsiloxy)silane, tetrakis(hydromethylphenylsiloxy)silane, 1,9-dihydro-1,1,9,9-tetramethyl-3,5,7-triphenylpentasiloxane, and 1,11-dihydro-1,1,11,11-tetramethyl-3,5,7,9-tetraphenylhexasiloxane, are commercially available from Dow Corning Corporation of Midland, Mich.

Component (B) has a number average molecular weight no greater than 1500, alternatively a number average molecular weight no greater than 1000, alternatively a number average molecular weight no greater than 900. In one embodiment, component (B) is of the general formula M^{H}_{0.4}T^{Ph}_{0.6} and has a number average molecular weight of ˜820. Generally, decreasing the number average molecular weight of the organohydrogensiloxane (B) correlates to lower viscosity, enabling easier dispense.

In certain embodiments, such as when component (B) is of the formula (IV) or (iv) as described above, component (B) is typically present in an amount ranging from 10 to 80, more typically from 25 to 70, most typically from 30 to 60, parts by weight, each based on 100 parts by weight of the composition. In other embodiments, such as when component (B) is of the formula (V) or (v) as described above, component (B) is typically present in an amount ranging from 10 to 80, more typically from 25 to 70, most typically from 30 to 60, parts by weight, based on 100 parts by weight of the composition. It is to be appreciated that component (B), and therefore the composition, may include any combination of two or more of the aforementioned organohydrogensiloxanes (B).

In certain embodiments, as alluded to above, the component (B) comprises the silicone resin and the siloxane. Both the silicone resin and siloxane are as described and exemplified above. In one embodiment, component (B) comprises the silicone resin of formula (IV) and the siloxane of formula (V). In a further embodiment, component (B) comprises the silicone resin of formula (Iv) and the siloxane of formula (v). In these embodiments, the silicone resin and the siloxane may be present in the composition in various weight ratios relative to one another. If both the silicone resin and the siloxane are present in the composition, the silicone resin and siloxane are typically present in the composition in a weight ratio (silicone resin:siloxane) ranging from 1:0.5 to 1:6.0. In one embodiment, the silicone resin and the siloxane are present in the composition in a weight ratio ranging from 1:0.5 to 1:1.5. In another embodiment, the silicone resin and the siloxane are present in the composition in a weight ratio ranging from 1:1.5 to 1:2. In yet another embodiment, the silicone resin and the siloxane are present in the composition in a weight ratio ranging from 1:2.5 to 1:3.5. In yet another embodiment, the silicone resin and the siloxane are present in the composition in a weight ratio ranging from 1:3.5 to 1:6.0. In these embodiments, increasing the amount of the silicone resin relative to the amount of the siloxane present in the composition generally imparts the product with increased modulus.

In certain embodiments, the composition (prior to fully curing) has a surface energy ranging from 19 to 33, more typically from 23 to 31, most typically from 28 to 30, dynes/cm. These embodiments are especially useful if the composition is used as a matrix for incorporation of other materials, such as particles and/or optical active agents, e.g. phosphors, all of which are described in further detail below. If such materials are incorporated, it is believed that matching a surface energy of the material to that of the composition provides for increased homogeneity of the composition and the materials incorporated therein.

In certain embodiments, the composition has a molar ratio of alkyl groups to aryl groups ranging from 1:0.25 to 1:3.0, more typically from 1:0.5 to 1:2.5, most typically from 1:1 to 1:2. The refractive index of the product may be increased or decreased by increasing or decreasing the number of aryl groups, e.g. phenyl groups, present in the composition, respectively.

The hydrosilylation catalyst component (C), hereinafter component (C), can include any one of the well-known hydrosilylation catalysts comprising a group VIII transition metal, typically a platinum group metal, e.g. platinum, rhodium, ruthenium, palladium, osmium, and iridium, and/or a compound containing a platinum group metal. In one embodiment, the platinum group metal is platinum, based on its high activity in hydrosilylation reactions. Specific examples of suitable hydrosilylation catalysts (C), for purposes of the present invention, include complexes of chloroplatinic acid, platinum dichloride, and certain vinyl-containing organosiloxanes disclosed by Willing in U.S. Pat. No. 3,419,593, which is hereby incorporated by reference. A catalyst of this type is the reaction product of chloroplatinic acid and 1,3-diethenyl-1,1,3,3-tetramethyldisiloxane. Other suitable hydrosilylation catalysts (C), for purposes of the present invention, are described in EP 0 347 895 B and U.S. Pat. Nos. 3,159,601; 3,220,972; 3,296,291; 3,516,946; 3,814,730; 3,989,668; 4,784,879; 5,036,117; and 5,175,325.

Component (C) can also include a microencapsulated platinum group metal-containing catalyst comprising a platinum group metal encapsulated in a thermoplastic resin. Microencapsulated hydrosilylation catalysts and methods of preparing them are well known in the catalytic art, as exemplified in U.S. Pat. No. 4,766,176 and the references cited therein, and U.S. Pat. No. 5,017,654.

Component (C) can also include a platinum di(acetylacetonate) photo-activated hydrosilylation catalyst. The photo-activated hydrosilylation catalyst can be any hydrosilylation catalyst capable of catalyzing the hydrosilylation reaction of components (A) and (B) upon exposure to radiation having a wavelength ranging from 150 to 800 nm. The photo-activated hydrosilylation catalyst can be any of the well-known hydrosilylation catalysts comprising a platinum group metal or a compound containing a platinum group metal. The platinum group metals include platinum, rhodium, ruthenium, palladium, osmium, and iridium. In one embodiment, the platinum group metal is platinum, based on its high activity in hydrosilylation reactions.

Specific examples of suitable photo-activated hydrosilylation catalysts, for purposes of the present invention, include, but are not limited to, platinum(II) β-diketonate complexes such as platinum(II) bis(2,4-pentanedioate), platinum(II) bis(2,4-hexanedioate), platinum(II) bis(2,4-heptanedioate), platinum(II) bis(1-phenyl-1,3-butanedioate, platinum(II) bis(1,3-diphenyl-1,3-propanedioate), platinum(II) bis(1,1,1,5,5,5-hexafluoro-2,4-pentanedioate); (η-cyclopentadienyl)trialkylplatinum complexes, such as (Cp)trimethylplatinum, (Cp)ethyldimethylplatinum, (Cp)triethylplatinum, (chloro-Cp)trimethylplatinum, and (trimethylsilyl-Cp)trimethylplatinum, where Cp represents cyclopentadienyl; triazene oxide-transition metal complexes, such as Pt[C₆H₅NNNOCH₃]₄, Pt[p-CN—C₆H₄NNNOC₆H₁₁]₄, Pt[p-H₃COC₆H₄NNNOC₆H₁₁]₄, Pt[p-CH₃(CH₂)ₓ—C₆H₄NNNOCH₃]₄, 1,5-cyclooctadiene.Pt[p-CN—C₆H₄NNNOC₆H₁₁]₂, 1,5-cyclooctadiene.Pt[p-CH₃O—C₆H₄NNNOCH₃]₂, [(C₆H₅)₃P]₃Rh[p-CN—C₆H₄NNNOC₆H₁₁], and Pd[p-CH₃(CH₂)ₓ—C₆H₄NNNOCH₃]₂, where x is 1, 3, 5, 11, or 17; (η-diolefin)(σ-aryl)platinum complexes, such as (η⁴-1,5-cyclooctadienyl)diphenylplatinum, η⁴-1,3,5,7-cyclooctatetraenyl)diphenylplatinum, (η⁴-2,5-norboradienyl)diphenylplatinum, (η⁴-1,5-cyclooctadienyl)bis-(4-dimethylaminophenyl)platinum, (η⁴-1,5-cyclooctadienyl)bis-(4-acetylphenyl)platinum, and (η⁴-1,5-cyclooctadienyl)bis-(4-trifluormethylphenyl)platinum. In certain embodiments, the photo-activated hydrosilylation catalyst is a Pt(II) β-diketonate complex, more typically platinum(II) bis(2,4-pentanedioate).

Methods of preparing photo-activated hydrosilylation catalysts are well known in the catalytic art. For example, methods of preparing platinum(II) β-diketonates are reported by Guo et al. (Chemistry of Materials, 1998, 10, 531-536); methods of preparing (η-cyclopentadienyl)-trialkylplatinum complexes are disclosed in U.S. Pat. No. 4,510,094; methods of preparing triazene oxide-transition metal complexes are disclosed in U.S. Pat. No. 5,496,961; and methods of preparing (η-diolefin)(σ-aryl)platinum complexes are disclosed in U.S. Pat. No. 4,530,879.

Component (C) is typically present in a catalytic amount, i.e., in an amount sufficient to catalyze the hydrosilylation reaction of the organopolysiloxane (A) and the organohydrogensiloxane (B). For example, the hydrosilylation catalyst (C) is typically present in an amount to provide from 2 to 10, more typically from 6 to 8, most typically 6, ppm of the group VIII transition metal, based on 100 parts by weight of the composition. Generally, the rate of reaction is slower below 2 ppm, and is vulnerable to inhibition of the catalyst and using more than 10 ppm can result in yellowing upon thermal aging of the hydrosilylation reaction product of the organopolysiloxane (A) and the organohydrogensiloxane (B), i.e., the product, which is described in further detail below. It is to be appreciated that component (C) may include any combination of two or more of the aforementioned hydrosilylation catalysts (C).

The composition may further comprise an additive selected from the group of optically active agents, e.g. phosphors; cure modifiers, e.g. catalyst-inhibitors; and combinations thereof. It is to be appreciated that the composition may include other additives known in the silicone art, some of which are further described below. For example, the composition may further comprise at least one of a co-crosslinker, an adhesion promoter, a filler, a treating agent, a rheology modifier, and combinations thereof. It is to be appreciated that the composition may include any combination of two or more of the aforementioned additives.

If included, any type of phosphor known in the art may be used. The phosphors are optionally included in the composition, and therefore the product, to adjust color emitted from the LED. The phosphors are generally any compound/material that exhibits phosphorescence. The phosphor material may be selected from the group of inorganic particles, organic particles, organic molecules, and combinations thereof. The aforementioned phosphor materials may be in the form of conventional bulk-particle powders, e.g. powders having an average diameter ranging from 1 to 25 um, and/or nanoparticle powders.

Suitable inorganic particles as the phosphor material, for purposes of the present invention, include, but are not limited to, doped garnets such as YAG:Ce and (Y,Gd)AG:Ce; aluminates such as Sr₂Al₁₄O₂₅:Eu, and BAM:Eu; silicates such as SrBaSiO:Eu; sulfides such as ZnS:Ag, CaS:Eu, and SrGa₂S₄:Eu; oxy-sulfides; oxy-nitrides; phosphates; borates; and tungstates such as CaWO₄. Other suitable inorganic particles, for purposes of the present invention, include quantum dot phosphors made of semiconductor nanoparticles including, but not limited to Ge, CdS, CdSe, CdTe, ZnS, ZnSe, ZnTe, PbS, PbSe, PbTe, InN, InP, InAs, AlN, AlP, AlAs, GaN, GaP, GaAs and combinations thereof. Generally, a surface of each quantum dot phosphor will be at least partially coated with an organic molecule to prevent agglomeration and increase compatibility. In certain embodiments, the phosphor, e.g. quantum dot phosphor, is made up of several layers of different materials in a core-shell construction. Suitable organic molecules for coating the surface of the quantum dot phosphor include, but are not limited to, absorbing dies and fluorescent dyes, such as those described in U.S. Pat. No. 6,600,175. Other suitable phosphors for purposes of the present invention are described in International Publication No. WO 2006/0600141 to Taskar et al., International Publication No. WO 2005/027576 to Taskar et al., U.S. Pat. No. 6,734,465 to Taskar et al., and U.S. Pat. No. 7,259,400 to Taskar at al., the disclosures of which pertaining to conventional and inventive phosphors are incorporated herein by reference in their entirety.

If employed, the amount of optically active agent used depends on various factors including the optically active agent selected and the end use application. If included, the optically active agent, e.g. phosphors, are typically present in an amount ranging from 0.01 to 25, more typically from 1 to 15, most typically from 5 to 10, parts by weight, each based on 100 parts by weight of the composition. The amount of optically active agent can be adjusted, for example, according to a thickness of a layer of the product containing the optically active agent and a desired color of emitted light. Other suitable optically active agents include photonic crystals and carbon nanotubes. It is to be appreciated that the composition may include any combination of two or more of the aforementioned optically active agents.

If included, any type of cure modifier known in the silicone art may be used. The cure modifier is optionally included in the composition to allow curing of the composition to be controlled after components (A), (B), and (C), are mixed together, which is described further below. The cure modifier is especially useful in the composition during formation of the product on the substrate, such as when making the LED. The cure modifier allows sufficient working time to be able to apply the composition onto the substrate prior to gelling and, ultimately, curing of the product.

The cure modifier can be added to extend the shelf life and/or the working time of the composition. The cure modifier can also be added to raise the curing temperature of the composition. Suitable cure modifiers are known in the silicone art and are commercially available. The cure modifier is exemplified by acetylenic alcohols, cycloalkenylsiloxanes, eneyne compounds, triazoles phosphines; mercaptans, hydrazines, amines, fumarates, maleates, and combinations thereof. Examples of acetylenic alcohols are disclosed, for example, in EP 0 764 703 A2 and U.S. Pat. No. 5,449,802 and include methyl butynol, ethynyl cyclohexanol, dimethyl hexynol, 1-butyn-3-ol, 1-propyn-3-ol, 2-methyl-3-butyn-2-ol, 3-methyl-1-butyn-3-ol, 3-methyl-1-pentyn-3-ol, 3-phenyl-1-butyn-3-ol, 4-ethyl-1-octyn-3-ol, 3,5-diemthyl-1-hexyn-3-ol, and 1-ethynyl-1-cyclohexanol, and combinations thereof. Examples of cycloalkenylsiloxanes include methylvinylcyclosiloxanes exemplified by 1,3,5,7-tetramethyl-1,3,5,7-tetravinylcyclotetrasiloxane, 1,3,5,7-tetramethyl-1,3,5,7-tetrahexenylcyclotetrasiloxane, and combinations thereof. Examples of eneyne compounds include 3-methyl-3-penten-1-yne, 3,5-dimethyl-3-hexen-1-yne, and combinations thereof. Examples of triazoles include benzotriazole. Examples of phosphines include triphenylphosphine. Examples of amines include tetramethyl ethylenediamine. Examples of fumarates include dialkyl fumarates, dialkenyl fumarates, dialkoxyalkyl fumarates, and combinations thereof. Suitable cure modifiers are disclosed by, for example, U.S. Pat. Nos. 3,445,420; 3,989,667; 4,584,361; and 5,036,117.

Alternatively, the cure modifier may comprise a silylated acetylenic inhibitor. Without being bound or limited to any particular theory, it is believed that adding a silylated acetylenic inhibitor reduces yellowing of the product prepared from the composition as compared to a product prepared from a hydrosilylation curable composition that does not contain an inhibitor or that contains an acetylenic alcohol.

Suitable silylated acetylenic inhibitors may have the general formula (V):

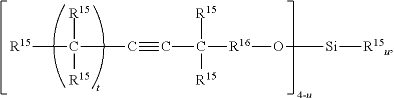

the general formula (VI):

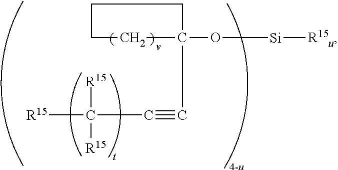

or a combination thereof; wherein each R¹⁵ is independently a hydrogen atom or a monovalent organic group, R¹⁶ is a covalent bond or a divalent hydrocarbon group, subscript u is 0, 1, 2, or 3, subscript t is 0 to 10, and subscript v is 4 to 12. Alternatively u is 1 or 3. Alternatively, in general formula (V) subscript u is 3. Alternatively, in general formula (VI) subscript u is 1, alternatively subscript t is 0, alternatively subscript v is 5, 6, or 7, and alternatively subscript v is 6. Examples of monovalent organic groups for R¹⁵ include an aliphatically unsaturated organic group, an aromatic group, or a monovalent substituted or unsubstituted hydrocarbon group free of aromatics and free aliphatic unsaturation, as described and exemplified above.

Suitable silylated acetylenic inhibitors are exemplified by (3-methyl-1-butyn-3-oxy)trimethylsilane, ((1,1-dimethyl-2-propynyl)oxy)trimethylsilane, bis(3-methyl-1-butyn-3-oxy)dimethylsilane, bis(3-methyl-1-butyn-3-oxy)silanemethylvinylsilane, bis((1,1-dimethyl-2-propynyl)oxy)dimethylsilane, methyl(tris(1,1-dimethyl-2-propynyloxy))silane, methyl(tris(3-methyl-1-butyn-3-oxy))silane, (3-methyl-1-butyn-3-oxy)dimethylphenylsilane, (3-methyl-1-butyn-3-oxy)dimethylhexenylsilane, (3-methyl-1-butyn-3-oxy)triethylsilane, bis (3-methyl-1-butyn-3-oxy)methyltrifluoropropylsilane, (3,5-dimethyl-1-hexyn-3-oxy)trimethylsilane, (3-phenyl-1-butyn-3-oxy)diphenylmethylsilane, (3-phenyl-1-butyn-3-oxy)dimethylphenylsilane, (3-phenyl-1-butyn-3-oxy)dimethylvinylsilane, (3-phenyl-1-butyn-3-oxy)dimethylhexenylsilane, (cyclohexyl-1-ethyn-1-oxy)dimethylhexenylsilane, (cyclohexyl-1-ethyn-1-oxy)dimethylvinylsilane, (cyclohexyl-1-ethyn-1-oxy)diphenylmethyl silane, (cyclohexyl-1-ethyn-1-oxy)trimethylsilane, and combinations thereof. Alternatively, the silylated acetylenic inhibitor may comprise methyl(tris(1,1-dimethyl-2-propynyloxy))silane, ((1,1-dimethyl-2-propynyl)oxy)trimethylsilane, and combinations thereof.

Silylated acetylenic inhibitors may be prepared by methods known in the art for silylating an alcohol such as reacting a chlorosilane of formula R¹⁵ᵤSiCl₄₋ᵤ, with an acetylenic alcohol of the general formula (VII):

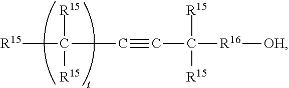

or the general formula (VIII):

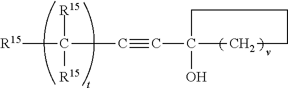

in the presence of an acid receptor.

In the general formulas (VII) and (VIII), each of R¹⁵, R¹⁶, and subscripts u, t, and v, are as described above. Examples of silylated acetylenic inhibitors and methods for their preparation are disclosed, for example, in EP 0 764 703 A2 and U.S. Pat. No. 5,449,802.

Other suitable cure modifiers, for purposes of the present invention, include, but are not limited to, methyl-butynol, 3-methyl-3-penten-1-yne, 3,5-dimethyl-3-hexen-1-yne, 3,5-dimethyl-1-hexyn-3-ol, 1-ethynyl-1-cyclohexanol, 2-phenyl-3-butyn-2-ol, vinylcyclosiloxanes, and triphenylphosphine. Other suitable cure modifiers include acetylenic alcohols such as those described in U.S. Pat. Nos. 3,989,666 and 3,445,420; unsaturated carboxylic esters such as those described in U.S. Pat. Nos. 4,504,645; 4,256,870; 4,347,346; and 4,774,111; and certain olefinic siloxanes such as those described in U.S. Pat. Nos. 3,933,880; 3,989,666; and 3,989,667. One specific example of a suitable cure modifier, for purposes of the present invention, is 3,5-dimethyl-1-hexyn-3-ol, commercially available from Air Products and Chemicals Inc, of Allentown, Pa., under the trade name Surfynol® 61.

If employed, the amount of the cure modifier added to the composition will depend on the particular cure modifier used, and the makeup and amounts of components (C), (A), and (B). If included, the cure modifier is typically present in an amount ranging from 1.0 to 10000, more typically from 25 to 500, most typically from 50 to 100, ppm, each based on 100 parts by weight of the composition. It is to be appreciated that various amounts may be used, depending on strength of the cure modifier. It is to be appreciated that the composition may include any combination of two of more of the aforementioned cure modifiers.

If employed, the co-crosslinker may be added to the composition in an amount ranging from 0.01 to 50, alternatively ranging from 0.01 to 25, alternatively ranging from 1 to 5, parts by weight, all based on 100 parts by weight of the composition. The co-crosslinker may comprise a hydrogensilyl functional polyorganosiloxane having an average compositional formula given as H_{c}R⁸_{d}SiO_{(4-c-d)/2}, wherein each R⁸ is independently a methyl group or a phenyl group, with at least 30 mol % of R⁸ being phenyl groups, subscripts a and b are positive numbers, and c+d=1 to 2.2 and c/(c+d)=0.001 to 0.05.

If employed, the adhesion promoter may be added to the composition in an amount ranging from 0.01 to 50, alternatively ranging from 0.01 to 10, alternatively ranging from 0.01 to 5, parts by weight, all based on 100 parts by weight of the composition. The adhesion promoter may comprise (a) an alkoxysilane, (b) a combination of an alkoxysilane and a hydroxy-functional polyorganosiloxane, or (c) a combination thereof, or a combination of component (a), (b) or (c) with a transition metal chelate. Alternatively, the adhesion promoter may comprise an unsaturated or epoxy-functional compound. Suitable epoxy-functional compounds are known in the silicone art and are commercially available; see e.g. U.S. Pat. Nos. 4,087,585; 5,194,649; 5,248,715; and 5,744,507 (col. 4-5). The adhesion promoter may comprise an unsaturated or epoxy-functional alkoxysilane. For example, the unsaturated or epoxy-functional alkoxysilane can have the formula R⁹ₑSi(OR¹⁰)₍₄₋ₑ₎, wherein subscript e is 1, 2, or 3, alternatively subscript e is 1. Each R⁹ is independently a monovalent organic group with the proviso that at least one R⁹ is an unsaturated organic group or an epoxy-functional organic group. Epoxy-functional organic groups for R⁹ are exemplified by 3-glycidoxypropyl and (epoxycyclohexyl)ethyl. Unsaturated organic groups for R⁹ are exemplified by 3-methacryloyloxypropyl, 3-acryloyloxypropyl, and unsaturated monovalent hydrocarbon groups such as vinyl, allyl, hexenyl, undecylenyl. Each R¹⁰ is independently an unsubstituted, saturated hydrocarbon group of 1 to 4 carbon atoms, alternatively 1 to 2 carbon atoms. R¹⁰ is exemplified by methyl, ethyl, propyl, and butyl.

Examples of suitable epoxy-functional alkoxysilanes include 3-glycidoxypropyltrimethoxysilane, 3-glycidoxypropyltriethoxysilane, (epoxycyclohexyl)ethyldimethoxysilane, (epoxycyclohexyl)ethyldiethoxysilane and combinations thereof. Examples of suitable unsaturated alkoxysilanes include vinyltrimethoxysilane, allyltrimethoxysilane, allyltriethoxysilane, hexenyltrimethoxysilane, undecylenyltrimethoxysilane, 3-methacryloyloxypropyl trimethoxysilane, 3-methacryloyloxypropyl triethoxysilane, 3-acryloyloxypropyl trimethoxysilane, 3-acryloyloxypropyl triethoxysilane, and combinations thereof.

The adhesion promoter may comprise an epoxy-functional siloxane such as a reaction product of a hydroxy-terminated polyorganosiloxane with an epoxy-functional alkoxysilane, as described above, or a physical blend of the hydroxy-terminated polyorganosiloxane with the epoxy-functional alkoxysilane. The adhesion promoter may comprise a combination of an epoxy-functional alkoxysilane and an epoxy-functional siloxane. For example, the adhesion promoter is exemplified by a mixture of 3-glycidoxypropyltrimethoxysilane and a reaction product of hydroxy-terminated methylvinylsiloxane with 3-glycidoxypropyltrimethoxysilane, or a mixture of 3-glycidoxypropyltrimethoxysilane and a hydroxy-terminated methylvinylsiloxane, or a mixture of 3-glycidoxypropyltrimethoxysilane and a hydroxy-terminated methylvinyl/dimethylsiloxane copolymer, or a mixture of 3-glycidoxypropyltrimethoxysilane and a hydroxy-terminated methylvinyl/methylphenylsiloxane copolymer. When used as a physical blend rather than as a reaction product, these components may be stored separately in multiple-part kits.

If employed, suitable transition metal chelates include titanates, aluminum chelates such as aluminum acetylacetonate, and combinations thereof. Transition metal chelates and methods for their preparation are known in the art, see e.g. U.S. Pat. No. 5,248,715; EP 0 493 791 A1; and EP 0 497 349 B1.

If employed, the amount of filler added to the composition depends on the type of filler selected and the resulting optical transparency. Filler may be added to the composition in an amount ranging from 0.1% to 50%, alternatively ranging from 0.1% to 25%, both based on the weight of the composition. Suitable fillers include reinforcing fillers, such as silica. Suitable reinforcing fillers are known in the art and are commercially available, such as a fumed silica sold under the name CAB-O-SIL by Cabot Corporation of Massachusetts.

Conductive fillers, i.e., fillers that are thermally conductive, electrically conductive, or both thermally and electrically conductive, may also be used as the filler. Suitable conductive fillers include metal particles, metal oxide particles, and combinations thereof. Suitable thermally conductive fillers are exemplified by aluminum nitride; aluminum oxide; barium titanate; beryllium oxide; boron nitride; diamond; graphite; magnesium oxide; metal particulate such as copper, gold, nickel, or silver; silicon carbide; tungsten carbide; zinc oxide, and combinations thereof.

Conductive fillers are known in the art and are commercially available; see e.g. U.S. Pat. No. 6,169,142 (col. 4, lines 7-33). For example, CB-A20S and Al-43-Me are aluminum oxide fillers of differing particle sizes, which are commercially available from Showa-Denko; and AA-04, AA-2, and AA18 are aluminum oxide fillers, which are commercially available from Sumitomo Chemical Company. Silver filler is commercially available from Metalor Technologies U.S.A. Corp. of Attleboro, Mass., U.S.A. Boron nitride filler is commercially available from Advanced Ceramics Corporation, Cleveland, Ohio, U.S.A.

The shape of the filler particles is not specifically restricted; however, rounded or spherical particles may prevent viscosity increase to an undesirable level upon high loading of the filler in the composition. A combination of fillers having differing particle sizes and different particle size distributions may be used. For example, it may be desirable to combine a first filler having a larger average particle size with a second filler having a smaller average particle size in a proportion meeting the closest packing theory distribution curve. This may improve packing efficiency and may reduce viscosity.

All or a portion of the filler may comprise spacers. Spacers can comprise organic particles such as polystyrene, inorganic particles such as glass, or combinations thereof. Spacers can be thermally conductive, electrically conductive, or both thermally and electrically conductive. Spacers can have a particle size of 25 micrometers to 250 micrometers. Spacers can comprise monodisperse beads. The amount of spacer depends on various factors including, for example, the distribution of particles, pressure to be applied during placement of the composition, and temperature of placement.

The filler may optionally be surface treated with the treating agent. Treating agents and treating methods are known in the art; see e.g. U.S. Pat. No. 6,169,142 (col. 4, line 42 to col. 5, line 2). The filler may be treated with the treating agent prior to combining the filler with the other components of the composition, or the filler may be treated in situ.

The treating agent can be an alkoxysilane having the formula: R¹¹_{f}Si(OR¹²)_{(4-f)}, wherein subscript f is 1, 2, or 3; alternatively subscript f is 3. Each R¹¹ is independently a substituted or unsubstituted monovalent hydrocarbon group of 1 to 50 carbon atoms. R¹¹ is exemplified by alkyl groups such as hexyl, octyl, dodecyl, tetradecyl, hexadecyl, and octadecyl; and aromatic groups such as benzyl, phenyl and phenylethyl. R¹¹ can be saturated or unsaturated, branched or unbranched, and unsubstituted. R¹¹ can be saturated, unbranched, and unsubstituted. Each R¹² is independently an unsubstituted, saturated hydrocarbon group of 1 to 4 carbon atoms, alternatively 1 to 2 carbon atoms. The treating agent is exemplified by hexyltrimethoxysilane, octyltriethoxysilane, decyltrimethoxysilane, dodecyltrimethyoxysilane, tetradecyltrimethoxysilane, phenyltrimethoxysilane, phenylethyltrimethoxysilane, octadecyltrimethoxysilane, octadecyltriethoxysilane, and combinations thereof.

Alkoxy-functional oligosiloxanes can also be used as treating agents. Alkoxy-functional oligosiloxanes and methods for their preparation are known in the silicone art, see e.g. EP 1 101 167 A2. For example, suitable alkoxy-functional oligosiloxanes include those of the formula (R¹³O)_{g}Si(OSiR¹⁴₂R¹⁵)_{4-g}, wherein subscript g is 1, 2, or 3, alternatively subscript g is 3. Each R¹³ can independently be an alkyl group. Each R¹⁴ can be independently selected from saturated and unsaturated monovalent hydrocarbon groups of 1 to 10 carbon atoms. Each R¹⁵ can be a saturated or unsaturated monovalent hydrocarbon group having at least 11 carbon atoms.

If employed, metal fillers can be treated with alkylthiols such as octadecyl mercaptan and others, and fatty acids such as oleic acid, stearic acid, titanates, titanate coupling agents, and combinations thereof. Treating agents for alumina or passivated aluminum nitride may include alkoxysilyl functional alkylmethyl polysiloxanes, e.g. partial hydrolysis condensate of R¹⁶ₕR¹⁷ᵢSi(OR¹⁸)₍₄₋ₕ₋ᵢ₎, or cohydrolysis condensates or mixtures, similar materials where the hydrolyzable group would be silazane, acyloxy or oximo. In all of these, a group tethered to Si, such as R¹⁶ in the formula above, is a long chain unsaturated monovalent hydrocarbon or monovalent aromatic-functional hydrocarbon. Each R¹⁷ is independently a monovalent hydrocarbon group, and each R¹⁸ is independently a monovalent hydrocarbon group of 1 to 4 carbon atoms. In the formula above, subscript h is 1, 2, or 3 and subscript i is 0, 1, or 2, with the proviso that h+i is 1, 2, or 3. One skilled in the silicone art can optimize a specific treatment to aid dispersion of the filler without undue experimentation.

The rheology modifiers can be added to change the thixotropic properties of the composition. The rheology modifier is exemplified by flow control additives; reactive diluents; anti-settling agents; alpha-olefins; non-reactive phenyl silsesquioxanes; hydroxyl terminated methylphenyl siloxane homopolymers; hydroxyl-terminated silicone-organic copolymers, including, but not limited to, hydroxyl-terminated polypropyleneoxide-dimethylsiloxane copolymers; and combinations thereof.

Other optional components may be added in addition to, or instead of, all or a portion of those additive components described above, provided the optional components do not prevent the composition from curing to form the product. Examples of other optional additives include, but are not limited to, acid acceptors; anti-oxidants; stabilizers such as magnesium oxide, calcium hydroxide, metal salt additives such as those disclosed in EP 0 950 685 A1, heat stabilizers, and ultra-violet (UV) stabilizers; flame retardants; silylating agents, such as 4-(trimethylsilyloxy)-3-penten-2-one and N-(t-butyl dimethylsilyl)-N-methyltrifluoroacetamide; desiccants, such as zeolites, anhydrous aluminum sulfate, molecular sieves (preferably with a pore diameter of 10 Angstroms or less), kieselguhr, silica gel, and activated carbon; optical diffusants; colloidal silica; and blowing agents, such as water, methanol, ethanol, iso-propyl alcohol, benzyl alcohol, 1,4 butanediol, 1,5 pentanediol, 1,7 heptanediol, and silanols. It is to be appreciated that the composition may include any combination of two or more of the aforementioned additive components.

The composition may be used alone, or may be used for incorporation of other materials, i.e., the composition may be used as a matrix for incorporation of other materials, such as the particles and/or the phosphors as described above. In certain embodiments, the composition further comprises at least one of metal-oxide particles and semiconductor particles. The metal-oxide particles and/or semiconductor particles can optionally be included in the composition to further increase a refractive index of the product, which is described in further detail below. Suitable metal-oxide particles and semiconductor particles are generally those that are substantially transparent over the emission bandwidth of the LED. “Substantially transparent” refers to the metal-oxide particles and/or semiconductor particles that are not capable of absorbing light emitted from the LED, i.e., the optical band-gap of the metal-oxide particles and/or semiconductor particles is greater than the photon energy of light emitted from the LED.

Suitable metal-oxide particles for purposes of the present invention include, but are not limited to, Al₂O₃, TiO₂, V₂O₅, ZnO, SnO₂, ZnS, and mixtures thereof. Suitable semiconductor particles for purposes of the present invention include, but are not limited to, ZnS, CdS, GaN, and mixtures thereof. In certain embodiments, the particles can include species that have a core of one material on which is deposited a material of another type.

In one embodiment, the metal-oxide particles comprise titanium dioxide (TiO₂). The TiO₂ particles are optionally included in the composition to adjust a refractive index of the composition and, specifically, to raise the refractive index of the composition after curing, e.g. to raise the refractive index of the product, which is described in further detail below. Individually, TiO₂ particles have a higher refractive index than the composition as a whole. By raising the refractive index of the composition, the refractive index can be more closely matched to the refractive index of the phosphors, when the phosphors are included in the composition.

If included, in certain embodiments, the metal-oxide particles and/or semiconductor particles are relatively large particles, e.g. TiO₂ particles that range in size from greater than one (1) micron, typically ranging from 1 to 20 microns, more typically from 1 to 10 microns, most typically from 1 to five (5) microns. In other embodiments, the metal-oxide particles and/or semiconductor particles are nanoparticles, e.g. TiO₂ nanoparticles, and range in size less than 1 micron, typically ranging from 5 to 300 nanometers, more typically from 10 to 90 nanometers, most typically from 30 to 70 nanometers. The aforementioned particle sizes are average particle sizes, wherein the particle size is based upon the longest dimension of the particles, which is a diameter for spherical particles.

In one embodiment, a mean particle size of nanoparticles, e.g. TiO₂ nanoparticles, is generally from 40 to 45 nanometers. Typically, ideal average diameter of the TiO₂ nanoparticles is from 20 to 50 nanometers. In certain embodiments, the TiO₂ nanoparticles have an average primary particle size less than 35, more typically less than 30, most typically less than 25, nanometers. The average particle size of the nanoparticles is generally less than a wavelength of light emitted by the substrate of the LED, if employed. As such, the nanoparticles do not scatter light emitted by the substrate, e.g. the diode, of the LED. A suitable fumed nano-TiO₂ particle is commercially available from Degussa of Parsippany, N.J. under the trade name P25. The nanoparticles (D) may be in free flowing powder form, more typically the nanoparticles (D) are in a solvent dispersion. A solvent of the solvent dispersion may be any solvent known in the art. If employed, the solvent selected will depend on various factors including the surface treatment of the nanoparticles (D). Typically, the solvent will be selected such that the polarity of the solvent may be the same as or close to the polarity of the surface treatment of the nanoparticles (D). For example, nanoparticles (D) with a nonpolar surface treatment may be dispersed in a hydrocarbon solvent, such as toluene. Alternatively, nanoparticles (D) with a polar surface treatment may be dispersed in a more polar solvent, such as water.

In certain embodiments, the TiO₂ nanoparticles are coated with a filler treating agent. Suitable filler treating agents, for purposes of the present invention, include the treating agent (or agents) as described and exemplified above. The filler treating agent typically comprises an alkoxysilane. In certain embodiments, the alkoxysilane is selected from the group of octyltrimethoxysilane, allyltrimethoxysilane, methacryloxypropyltrimethoxysilane, and combinations thereof. Suitable alkoxysilanes, for purposes of the present invention, are commercially available from Gelest, Inc. of Morrisville, Pa.

In one embodiment, the TiO₂ nanoparticles have an outer shell-coating between the TiO₂ nanoparticle and the filler treating agent coating. It is to be appreciated that the TiO₂ nanoparticles may also have the outer shell-coating even if the filler treating agent is not employed. If employed, the outer shell-coating typically comprises a material having a bandgap larger than a bandgap of the TiO₂ nanoparticle. The material having a larger bandgap is generally an oxide. In certain embodiments, the oxide is aluminum oxide. Suitable TiO₂ nanoparticles such as those described above, methods of making the same, and other suitable TiO₂ nanoparticles for purposes of the present invention, are described in International Publication No. WO 2006/0600141 to Taskar et al., the disclosure of which pertaining to both conventional and inventive TiO₂ nanoparticles is incorporated herein by reference in its entirety. In other embodiments, the metal-oxide nanoparticles are the modified nanoparticles disclosed in U.S. Patent Application No. 61/420,925 filed concurrently with the subject application, the disclosure of which is incorporated by reference in its entirety. Further suitable metal-oxide particles, for purposes of the present invention, are commercially available from Sumitomo Osaka Cement Co., Ltd. and from Tayca Corporation, both of Japan.

If included, the particles, e.g. TiO₂ nanoparticles, are typically present in an amount ranging from 60 to 75, more typically from 60 to 70, most typically from 65 to 70, parts by weight, each based on 100 parts by weight of the composition. It is to be appreciated that the composition may include any combination of the aforementioned particles.

The composition typically has a molar ratio of SiH groups to alkenyl groups ranging from 0.80 to 1.5, more typically from 1.0 to 1.5, most typically from 1.0 to 1.1. It is generally understood by those skilled in the silicone art that cross-linking occurs when the sum of the average number of alkenyl groups per molecule of component (A) and the average number of silicon-bonded hydrogen atoms per molecule of component (B) is greater than four.

Components (A), (B), and (C), and optionally, one or more of the additives and/or the metal-oxide particles and/or semiconductor particles, can be combined in any order. Typically, components (A) and (B) are combined before the introduction of component (C).

The composition may be supplied to consumers for use by various means, such as in large-sized tanks, drums and containers or small-sized kits, packets, and containers. The composition may be supplied in a one-part, a two-part, or a multi-part system. Typically, any of the components having alkenyl groups, e.g. component (A), are kept separate from any of the components having SiH groups, e.g. component (B), to prevent premature reaction of the composition. Additional components such as component (C), and optionally, one of more of the additives and/or the metal-oxide particles and/or semiconductor particles, may be combined with either of the previous described components (A) and (B), or kept separate therefrom. In one example of a two-part system, one kit contains components (A) and (C), and another kit contains component (B) and the cure modifier.

As described above, the product comprises the reaction product of components (A) and (B) in the presence of component (C), and optionally, one or more of the additives and/or the metal-oxide particles and/or semiconductor particles. The product typically has the molar ratio of alkyl groups to phenyl groups as described above with the composition.

After cure, the product typically has a refractive index ranging from 1.40 to 1.60, more typically from 1.43 to 1.56, most typically from 1.50 to 1.56, measured at 632.8 nm wavelength. The refractive index can be determined using a prism-coupler. This method uses advanced optical wave guiding techniques to accurately measure refractive index at specific wavelengths. The product typically has an optical transparency at 0.1 mm thickness of at least 85%, more typically at least 90%, most typically least 95%, transmission of light of 632.8 nm wavelength. The optical transparency can be determined using a UV-spectrophotometer, using methods known to those skilled in the silicone art.

The product typically has a modulus of at least 9.0×10⁵, more typically from 9.0×10⁵ to 5.0×10⁷, dyn/cm², as measured in a controlled strain, parallel plate, oscillating rheometer. In certain embodiments, the product has a modulus ranging from 9.0×10⁵ to 5.0×10⁶ dyn/cm². In other embodiments, the product has a modulus ranging from 5.0×10⁶ to 1.0×10⁷ dyn/cm². In further embodiments, the product has a modulus ranging from 1.0×10⁷ to 5.0×10⁷ dyn/cm².

The product typically has a Shore A hardness greater than 50, more typically a Shore D hardness ranging from 5 to 40, yet more typically a Shore D hardness ranging from 10 to 30, most typically a Shore D hardness ranging from 10 to 25. Hardness of the product can be determined according to ASTM D-2240.

The reaction to form the product from the composition can be carried out in any standard reactor suitable for hydrosilylation reactions known to those skilled in the silicone art. Suitable reactors for purposes of the present invention include, but are not limited to, glass reactors and Teflon®-lined glass reactors. Preferably, the reactor is equipped with a means of agitation, such as stirring or other means of imparting shear mixing.

The reaction of the composition to form the product is typically carried out at a temperature ranging from 0° C. to 200° C., more typically from room temperature (−23±2° C.) to 150° C., most typically from 80° C. to 150° C. The reaction time depends on several factors, such as the amounts and makeup of components (A) and (B), stiffing, and the temperature. The time of reaction is typically from ½ hour (30 minutes) to 24 hours at a temperature ranging from room temperature (−23±2° C.) to 150° C. In one embodiment, the time of reaction is two hours at 125° C. In another embodiment, the time of reaction is ½ hour (30 minutes) at 150° C. It is to be appreciated, that the mixed composition is typically applied to the substrate using various known methods, after which the reaction is carried out as set forth above. Encapsulation or coating techniques for LEDs are well known to the art. Such techniques include casting, dispensing, molding, and the like. For example, after the LED is encapsulated in the composition, typically performed in a mold, the composition is reacted, i.e., cured, at temperature ranges and times as described and exemplified above. It is to be appreciated that the composition may be cured in one or more stages, e.g. by two or more heating stages, to form the product.

As described above, the compositions and the products formed therefrom are useful for encapsulating LEDs, which can be any type of LED known in the art. LEDs are well known in the art; see e.g. E. FRED SCHUBERT, LIGHT-EMITTING DIODES (2d ed. 2006). LEDs include the diode, i.e., the substrate, which emits light, whether visible, ultraviolet, or infrared. The diode can be an individual component or a chip made, for example, by semiconductor wafer processing procedures. The component or the chip can include electrical contacts suitable for application of power to energize the diode. Individual layers and other functional elements of the component or the chip are typically formed on the wafer scale, the finished wafer finally being diced into individual piece parts to yield a multiplicity of the diodes.

The compositions and the products described herein are useful for making a wide variety of LEDs, including, but not limited to, monochrome and phosphor-LEDs (in which blue or UV light is converted to another color via the phosphor). The LEDs may be packaged in a variety of configurations, including, but not limited to, LEDs surface mounted in ceramic or polymeric packages, which may or may not have a reflecting cup; LEDs mounted on circuit boards; LEDs mounted on plastic electronic substrates; etc.

LED emission light can be any light that an LED source can emit and can range from the UV to the visible portions of the electromagnetic spectrum depending on the composition and structure of semiconductor layers. The compositions and the products described herein are useful in surface mount and side mount LED packages where the encapsulant, i.e., the product, is cured in a reflector cup. The compositions and the products are also useful with LED designs containing a top wire bond. Additionally, the compositions and the products can be useful for making surface mount LEDs where there is no reflector cup and can be useful for making arrays of surface mounted LEDs attached to a variety of different substrates.

The products described herein are resistant to physical, thermal and photo-degradation (resistant to yellowing) and thus are particularly useful for white light sources, e.g. white LEDs. White light sources that utilize LEDs in their construction generally have two basic configurations. In one, referred to herein as direct emissive LEDs, white light is generated by direct emission of different colored LEDs. Examples include a combination of a red LED, a green LED, and a blue LED, and a combination of a blue LED and a yellow LED. In the other basic configuration, referred to herein as LED-excited phosphor-based light sources, a single LED generates light in a narrow range of wavelengths, which impinges upon and excites the phosphor (or phosphors) to produce visible light. As previously described, the phosphor can comprise a mixture or combination of distinct phosphor materials. The light emitted by the phosphor can include a plurality of narrow emission lines distributed over the visible wavelength range such that the emitted light appears substantially white to an unaided human eye. The phosphor may be applied to the diode to form the LED as part of the composition. Alternatively or in addition to, the phosphor may be applied to the diode in a separate step, for example, the phosphor may be coated onto the diode prior to contacting the diode with the composition to form the encapsulant, i.e., the product.

An example of obtaining white light from an LED is to use a blue LED illuminating a phosphor that converts blue to both red and green wavelengths. A portion of the blue excitation light is not absorbed by the phosphor, and the residual blue excitation light is combined with the red and green light emitted by the phosphor. Another example of an LED is an ultraviolet (UV) LED illuminating a phosphor that absorbs and converts UV light to red, green, and blue light. Embodiments of the composition having groups that are small and have minimal UV absorption, e.g. methyl groups, are preferred for UV LEDs. Typically, both the phosphors, if included, and the diode, have refractive indexes that are higher than that of the product. Light scattering can be minimized by matching the refractive index of the product and the phosphors and/or the diode.

The following examples, illustrating the compositions and products of the present invention, are intended to illustrate and not to limit the present invention.

### EXAMPLES

Eight examples, specifically Examples 1-8 of the compositions of the present invention were prepared. Components (A), (B), (C), and the cure modifier were mixed in a reaction vessel to form the respective examples of the composition. The reaction vessel was a container capable of withstanding agitation and having resistance to chemical reactivity. The compositions were mixed using a high shear centrifical mixer for 1 to 3 minutes at 2000 to 3500 rpm. Viscosities of the compositions were determined using a Brookfield Cone and Plate Viscometer according to ASTM D-4287. The mixed compositions were heated to a temperature ranging from 80° C. to 125° C. to facilitate reaction of the compositions to form the respective products. The products cured, i.e., formed, in 30 to 120 minutes. Moduli of the products were determined using a parallel plate dynamic mechanical rheometer according to ASTM D-4440 and D-4065. Refractive indices of the products were determined using a prism coupler. This method uses advanced optical wave guiding techniques to accurately measure refractive index at specific wavelengths. Optical transparency of the product was determined using a UV-spectrophotometer, using methods known to those skilled in the silicone art.

The amount and type of each component used to form the compositions are indicated in Table 1 below with all values in parts by weight based on 100 parts by weight of the compositions unless otherwise indicated. The symbol ‘x’ indicates that the property was not measured. The symbol ‘−’ indicates that the component is absent from the formulation.

TABLE 1

| | Example | | | | | | | |
|---|---|---|---|---|---|---|---|---|
| Component | 1 | 2 | 3 | 4 | 5 | 6 | 7 | 8 |
| Organopolysiloxane 1 (g) | 44.44 | 36.36 | 33.93 | 38.99 | | | | |
| Organopolysiloxane 2 (g) | — | — | — | — | 27.59 | — | — | — |
| Organopolysiloxane 3 (g) | — | — | — | — | — | 24.38 | 28.96 | — |
| Organopolysiloxane 4 (g) | — | — | — | — | — | — | — | 24.06 |
| Organohydrogensiloxane | 55.56 | 22.73 | 15.18 | 35.30 | — | 44.25 | 71.04 | — |
| 1 (g) | | | | | | | | |
| Organohydrogensiloxane | — | 40.91 | 50.89 | 25.71 | 72.41 | 31.38 | — | 75.94 |
| 2 (g) | | | | | | | | |
| Catalyst (ppm) | 6 | 6 | 6 | 6 | 6 | 6 | 6 | 6 |
| Cure modifier (ppm) | 50 | 50 | 50 | 50 | 50 | 50 | 50 | 50 |
| Surface Energy | 28.28 | 30.81 | 31.39 | 29.86 | 30.44 | 26.72 | 23.99 | 30.07 |
| Refractive Index | 1.534 | 1.5353 | 1.5577 | 1.546 | 1.546 | 1.506 | 1.49 | 1.537 |
| (@ 632.8 nm) | | | | | | | | |
| Modulus (dyn/cm²) | >4.E+7 | 4.0E+06 | 9.5E+05 | x | x | x | x | x |
| Shore D Hardness | 25 | 17 | 9 | x | 5 | x | 29 | 15 |

Organopolysiloxane 1 is 1,3-dimethyl-1,3-diphenyl-1,3-divinyldisiloxane, available from Dow Corning Corporation of Midland, Mich.

Organopolysiloxane 2 is 1,4-divinyl-3-(dimethylvinylsiloxy)-1,1,5,5-tetramethyl-3-phenyltrisiloxane, available from Dow Corning Corporation.

Organopolysiloxane 3 is 1,1,3,3-tetramethyl-1,3-divinyldisiloxane, available from Dow Corning Corporation.

Organopolysiloxane 4 is tetrakis(vinyldimethylsiloxy)silane, available from Dow Corning Corporation.

Organohydrogensiloxane 1 is a silicone resin having the formula (T^{Ph})_{0.4}(M^{H})_{0.6}, wherein T is SiO_{3/2}, M is Me₂SiO_{1/2}, Ph is a phenyl group, H is a hydrogen atom, and Me is a methyl group, available from Dow Corning Corporation.

Organohydrogensiloxane 2 is a siloxane, more specifically, 1,1,5,5-tetramethyl-3,3-diphenyltrisiloxane, available from Dow Corning Corporation.

Catalyst is a platinum catalyst.

Cure modifier is 3,5-dimethyl-1-hexyn-3-ol, commercially available from Air Products and Chemicals Inc, of Allentown, Pa., under the trade name Surfynol® 61.

Examples 1-8 of the compositions were homogenous and had low viscosities which were useful for easily dispensing and forming various shapes of the product. Optical transparency of all of the products was deemed to be at least 95% transparent. The products formed from the examples had sufficient moduli and appropriate refractive indices for the application.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9”includes various individual integers, such as 3, as well as individual numbers including a decimal point (or fraction), such as 4.1, which may be relied upon and provide adequate support for specific embodiments within the scope of the appended claims. The subject matter of all combinations of independent and dependent claims, both singly and multiply dependent, is herein expressly contemplated.

The invention has been described in an illustrative manner, and it is to be understood that the terminology which has been used is intended to be in the nature of words of description rather than of limitation. Many modifications and variations of the present invention are possible in light of the above teachings, and the invention may be practiced otherwise than as specifically described.

1. A composition comprising:
(A) an organopolysiloxane component comprising at least one of a disiloxane, a trisiloxane, and a tetrasiloxane, and having at least one of an alkyl group and an aryl group and having an average of at least two alkenyl groups per molecule, with a number average molecular weight no greater than 1500 (g/mole);
(B) an organohydrogensiloxane component having at least one of an alkyl group and an aryl group and having an average of at least two silicon-bonded hydrogen atoms per molecule, with a number average molecular weight no greater than 1500 (g/mole); and
(C) a catalytic amount of a hydrosilylation catalyst component.

2. The composition of claim 1, having a surface energy ranging from 19 to 33 dynes/cm.

3. The composition of claim 1, having a molar ratio of alkyl groups to aryl groups ranging from 1:0.25 to 1:3.0.

4. The composition of claim 1, where component (A) comprises the disiloxane having the formula:
R¹R²R³SiOSiR¹R²R³ (I)
wherein each R¹, R², and R³ independently comprises an alkyl group, an aryl group, or an alkenyl group; or
ViPhMeSiOSiViPhMe (i)
wherein Vi is a vinyl group, Ph is a phenyl group, and Me is a methyl group.

5. (canceled)

6. The composition of claim 1, where component (A) comprises at least one of the trisiloxane and the tetrasiloxane, each of the trisiloxane and the tetrasiloxane independently having the formula:
(R¹R³₂SiO)₄₋ₐSiR⁴ₐ (II)
wherein each R¹ and R³ independently comprises an alkyl group, an aryl group, or an alkenyl group, R⁴ comprises an alkyl group or an aryl group, and subscript a is 0 for the tetrasiloxane or 1 for the trisiloxane; or
(ViR³₂SiO)₄₋ₐSiR⁴ₐ (ii)
wherein Vi is a vinyl group, each R³ and R⁴ independently comprises a phenyl group or a methyl group, and subscript a is 0 for the tetrasiloxane or 1 for the trisiloxane.

7-9. (canceled)

10. The composition of claim 1, where component (B) comprises a silicone resin having the formula:
(R⁶R⁷₂SiO_{1/2})_{y}(R⁵SiO_{3/2})ₓ (IV)
wherein each R⁵ and R⁶ independently comprises an alkyl group, an aryl group, an alkenyl group, or a hydrogen atom, each R⁷ independently comprises an alkyl group, an aryl group, or an alkenyl group, subscript x ranges from 0.2 to 0.6, and x+y=1; or
(HR⁷₂SiO_{1/2})_{y}(R⁵SiO_{3/2})ₓ (iv)
wherein each R⁵ and R⁷ independently comprises a phenyl group or a methyl group, subscript x ranges from 0.2 to 0.6, and x+y=1.

11. (canceled)

12. The composition of claim 1, where component (B) comprises a siloxane having the formula:
(R⁶R⁷₂SiO)(R⁵₂SiO)_{z}(SiR⁶R⁷₂) (V)
wherein each R⁵ and R⁶ independently comprises an alkyl group, an aryl group, an alkenyl group, or a hydrogen atom, each R⁷ independently comprises an alkyl group, an aryl group, or an alkenyl group, and subscript z≧1; or
(HR⁷₂SiO)(R⁵₂SiO)_{z}(SiHR⁷₂) (v)
wherein each R⁵ and R⁷ independently comprises a phenyl group or a methyl group, and 5≧z≧1.

13. (canceled)

14. The composition of claim 1, where:
i) component (A) is present in an amount ranging from 20 to 50 parts by weight and component (B) is present in an amount ranging from 10 to 80 parts by weight, each based on 100 parts by weight of the composition;
ii) component (C) is present in an amount sufficient to provide 2 to 10 ppm of a group VIII transition metal, based on 100 parts by weight of the composition; or
iii) both i) and ii).

15. (canceled)

16. The composition of claim 1, having a molar ratio of SiH groups to alkenyl groups ranging from 1.0 to 1.5.

17. The composition of claim 1, further comprising at least one of:
i) metal-oxide particles and semiconductor particles;
ii) a co-crosslinker, an adhesion promoter, a filler, a treating agent, an optically active agent, a cure modifier, and a rheology modifier; or
iii) both i) and ii).

18. (canceled)

19. A composition comprising:
(A) an organopolysiloxane component having an average of at least two alkenyl groups per molecule and selected from the group of:
R¹R²R³SiOSiR¹R²R³, (I)
(R¹R³₂SiO)₄₋ₐSiR⁴ₐ, (II)
and combinations thereof; and
(B) an organohydrogensiloxane component having an average of at least two silicon-bonded hydrogen atoms per molecule and selected from the group of:
(R⁶R⁷₂SiO_{1/2})_{y}(R⁵SiO_{3/2})ₓ, (IV)
(R⁶R⁷₂SiO)(R⁵₂SiO)_{z}(SiR⁶R⁷₂), (V)
and combinations thereof;
wherein each R¹, R², R³, and R⁷ independently comprises an alkyl group, an aryl group, or an alkenyl group, R⁴ comprises an alkyl group or an aryl group, each R⁵ and R⁶ independently comprises an alkyl group, an aryl group, an alkenyl group, or a hydrogen atom, subscript a is 0 or 1, subscript y ranges from 0.2 to 0.6, x+y=1, and subscript z≧1, provided each of component (A) and component (B) independently has at least one of an alkyl group and an aryl group; and
(C) a catalytic amount of a hydrosilylation catalyst component.

20. The composition of claim 19, where component (A) is selected from the group of:
ViPhMeSiOSiViPhMe, (i)
(ViR³₂SiO_{1/2})₄₋ₐSiR⁴ₐ, (ii)
and combinations thereof; and
component (B) is selected from the group of:
(HR⁷₂SiO_{1/2})_{y}(R⁵SiO_{3/2})ₓ, (iv)
(HR⁷₂SiO)(R⁵₂SiO)_{z}(SiHR⁷₂), (v)
and combinations thereof;
wherein Vi is a vinyl group, each R³, R⁴, R⁵, and R⁷ independently comprises a phenyl group or a methyl group, subscript a is 0 or 1, subscript x ranges from 0.2 to 0.6, x+y=1, and 5≧z≧1.

21. The composition of claim 20, having a surface energy ranging from 19 to 33 dynes/cm.

22. A product comprising the reaction product of the composition as set forth in claim 1,
wherein the product has:
i) a refractive index ranging from 1.40 to 1.60 at 632.8 nm wavelength;
ii) a modulus greater than 8×10⁵ dyn/cm²; or
iii) both i) and ii).

23-24. (canceled)

25. The product of claim 22, having a refractive index ranging from 1.50 to 1.56 at 632.8 nm wavelength.

26. The product of claim 22, having a Shore A hardness greater than 50.

27-36. (canceled)

37. The product of claim 22, having a modulus ranging from 9.0×10⁵ to 5.0×10⁷ dyn/cm².

38-39. (canceled)

40. A light emitting diode comprising:
a substrate; and
an encapsulant at least partially surrounding the substrate and comprising a reaction product of a composition comprising;
(A) an organopolysiloxane component comprising at least one of a disiloxane, a trisiloxane, and a tetrasiloxane, and having at least one of an alkyl group and an aryl group and having an average of at least two alkenyl groups per molecule, and
(B) an organohydrogensiloxane component having at least one of an alkyl group and an aryl group and having an average of at least two silicon-bonded hydrogen atoms per molecule,
in the presence of
(C) a catalytic amount of a hydrosilylation catalyst component;
with the proviso that the encapsulant has a refractive index ranging from 1.40 to 1.60 at 632.8 nm wavelength.

41. The light emitting diode of claim 40, where the encapsulant has a Shore A hardness greater than 50.

42. The light emitting diode of claim 40, where the substrate is a light emitting diode source emitting light in the range from UV to visible portions of the electromagnetic spectrum.
